(19) United States
(12) Patent Application Publication
(10) Pub. No.: US 2010/0203245 A1
(43) Pub. Date: Aug. 12, 2010

(54) FABRICATION METHOD OF A PHOTONIC CRYSTAL STRUCTURE

(76) Inventors: Shiuh Chao, Hsinchu (TW); Chen-Yang Huang, Hsinchu (TW); Hao-Min Ku, Hsinchu (TW)

Correspondence Address: Muncy, Geissler, Olds & Lowe, PLLC, 4000 Legato Road, Suite 310, FAIRFAX, VA, 22033, US

(21) Appl. No.: 12/416,705

(22) Filed: Apr. 1, 2009

(30) Foreign Application Priority Data
Feb. 10, 2009 (TW) 98104168

(51) Int. Cl. C23C 16/40; B05D 5/00; C23C 14/34; C23C 16/00; C23C 16/06

(52) U.S. Cl. 427/255.33; 427/256; 427/255.28; 204/192.1; 427/255.31; 427/255.36; 427/255.37

(57) ABSTRACT

A method for fabricating a photonic crystal structure is disclosed herein for forming a cavity-type or a pillar type photonic crystal structure of a large area. By the property that a hetero-interface inhibits epitaxial growth, a patterned film layer is formed over the epitaxy substrate, so a photonic crystal structure is grown vertically by epitaxy in area outside of the patterned film layer on the epitaxy substrate. Furthermore, by designing the pattern of the patterned film, a defect mode photonic crystal structure such as an optical waveguide, an optical resonator and a beam splitter can be formed.

### BACKGROUND OF THE INVENTION

1. Field of the Invention

The present invention relates to a fabrication method of an optical element, and more particularly to a fabrication method of a photonic crystal structure.

2. Description of the Related Art

Since Eli Yablonovitch and Sajeev John proposed the concept of photonic crystals in 1987, there have been many applications and fabrication methods developed. Photonic crystal structures can be applied to optical elements such as omni-directional reflectors, super-prisms, resonant filters, and waveguides. However, in order for the photonic crystals to be used for visible light applications, fabrication difficulties need to be resolved. Since the structural size has to be sub-wavelength for the energy band to fall within visible light range, commercialized, large area and low cost fabrication is indeed a challenge.

### SUMMARY OF THE INVENTION

The present invention provides a fabrication method of a photonic crystal structure. Based on the property that a hetero-interface inhibits epitaxial growth, a patterned film layer is formed on an epitaxy substrate, so a self-constructed cavity-type or pillar-type photonic crystal structure is grown vertically by epitaxy in area outside of the patterned film layer.

One embodiment provides a fabrication method of a photonic crystal structure. By designing the pattern of a patterned film layer, a defect mode photonic crystal structure can be grown epitaxially, which can be applied to optical elements such as a waveguide, a resonator, and a beam splitter.

One embodiment provides a fabrication method of a photonic crystal structure including the following steps: providing a substrate; forming a patterned film layer on the substrate, wherein the patterned film layer includes a plurality of pattern members arranged periodically on the substrate; and forming a photonic crystal layer by an epitaxy procedure on the substrate, with each pattern member exposed.

### BRIEF DESCRIPTION OF THE DRAWINGS

The objectives, technical contents and characteristics of the present invention can be more fully understood by reading the following detailed description of the preferred embodiments, with reference made to the accompanying drawings.

FIG. 1A and FIG. 1B are diagrams illustrating different embodiments.

FIG. 2A, FIG. 2B, FIG. 2C and FIG. 2D are diagrams illustrating one embodiment.

FIG. 3A, FIG. 3B and FIG. 3C are diagrams illustrating one embodiment.

FIG. 4A and FIG. 4B are diagrams illustrating one embodiment.

FIG. 5A and FIG. 5B are diagrams illustrating one embodiment.

FIG. 6A, FIG. 6B, FIG. 6C, FIG. 6D, FIG. 6E and FIG. 6F are diagrams illustrating different embodiments.

FIG. 7A, FIG. 7B, FIG. 7C, FIG. 7D, FIG. 7E and FIG. 7F are diagrams illustrating different embodiments.

FIG. 8A, FIG. 8B and FIG. 8C are diagrams illustrating different embodiments.

FIG. 9 is a diagram illustrating one embodiment.

### DETAILED DESCRIPTION OF THE INVENTION

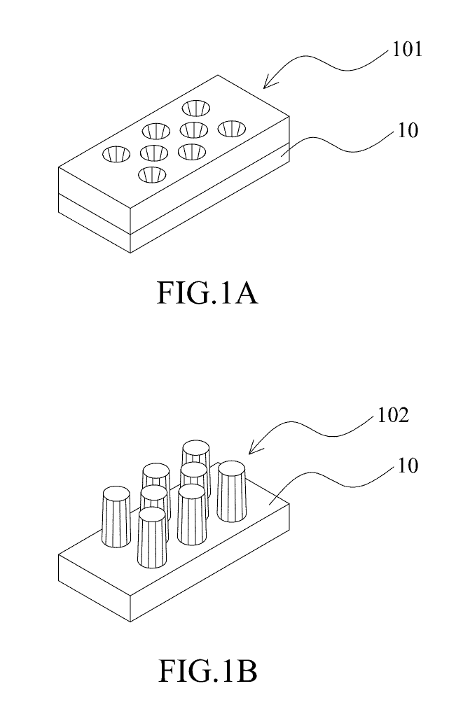

One embodiment discloses a fabrication method of a photonic crystal structure, which can be applied to fabricating a photonic crystal structure of a large area. According to the embodiment, a patterned film layer is formed on the substrate, and by applying the property that a hetero-interface (i.e. interface between materials of significantly different lattice constants) inhibits epitaxial growth, a pillar-type 102 or a cavity-type 101 photonic crystal structure formed in area outside of the patterned film layer by material homogenous to the substrate 10 can be grown vertically on the substrate 10 by itself, as illustrated in FIG. 1A and FIG. 1B. Of course, the present invention is not limited to this embodiment. A structure combining cavity-type, pillar-type and other types of photonic crystal structures can also be fabricated.

According to one embodiment, a fabrication method of a photonic crystal structure includes the following steps. First, a substrate is provided. Next, a patterned film layer is formed on the substrate, and such patterned film layer includes a plurality of pattern members arranged periodically on the substrate. Then, a photonic crystal layer is formed on the substrate by an epitaxy procedure and such photonic crystal layer includes a plurality of photonic crystals arranged periodically on the substrate, with each pattern member exposed.

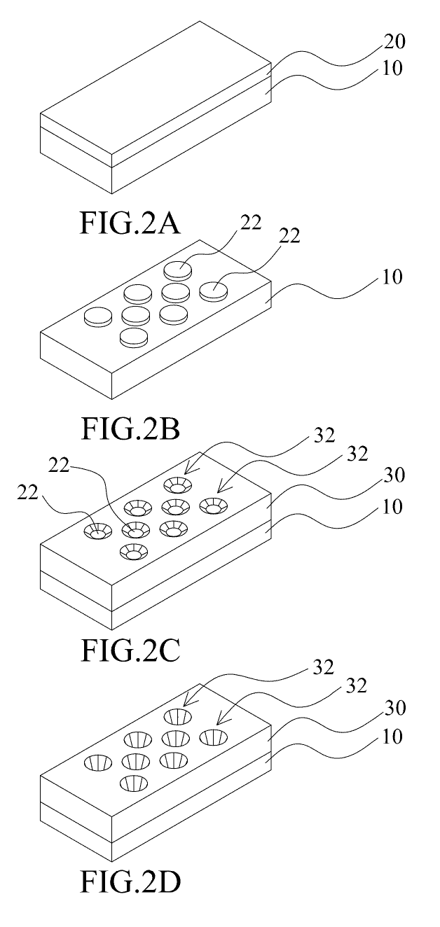

FIG. 2A, FIG. 2B, FIG. 2C and FIG. 2D illustrate the flow of a fabrication method of a photonic crystal structure according to one embodiment. In this embodiment, a patterned film layer (not illustrated in the diagram) is formed by depositing a film layer 20 on the substrate 10, and then a portion of the film layer 20 is removed to expose the substrate 10 for forming the patterned film layer, as illustrated in FIG. 2A and FIG. 2B. The film layer 20 may be patterned by known methods such as lithography, nano-imprint or micro-contact printing, wherein lithography can be photolithography, interference lithography, etc. In this embodiment, the patterned film layer includes a plurality of island pattern members 22 periodically arranged. In a different embodiment, the patterned film layer includes a plurality of cavity pattern members. Then, as illustrated in FIG. 2C, after carrying out an epitaxy procedure, a photonic crystal structure of a plurality of periodically arranged photonic crystal cavities 32 are grown on the area not covered by the island pattern members 22. Next, island pattern members 22 can be removed as required to finish the fabrication of a cavity-type photonic crystal structure, as illustrated in FIG. 2D. An etching procedure employing dry or wet etch can be used to remove the patterned film layer.

In continuation to the above description, the material of the substrate 10 is selected from the following group: sapphire, SiC, Si, GaAs, LiAlO₂, LiGaO₂ and AlN; the material of the film layer 20 is selected from the following group: TiO₂, Ta₂O₅, Nb₂O₅, CeO₂, ZnO, and SiO₂; and the material of the photonic crystal layer 30 is selected from group III-V semiconductor materials, such as GaN, GaAs, GaInN. Also, the film layer 20 is formed by sputtering (such as ion beam sputtering or magnetic enhanced sputtering), evaporation, chemical vapor deposition, chemical liquid deposition, chemical vapor epitaxy or chemical liquid epitaxy. Moreover, for the epitaxy procedure, techniques such as molecular beam epitaxy (MBE), metal organic chemical vapor deposition (MOCVD) or liquid phase epitaxy (LPE) can be employed.

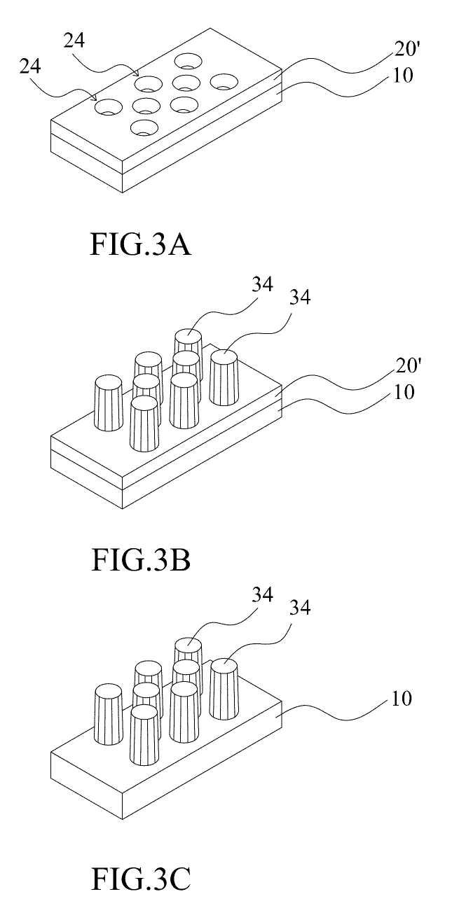

FIG. 3A, FIG. 3B and FIG. 3C illustrates the flow of a fabrication method of a photonic crystal structure according to one embodiment. In this embodiment, a patterned film layer 20′ comprising a plurality of cavity pattern members 24 is formed directly on a substrate 10, as illustrated in FIG. 3A. Methods for fabricating the patterned film layer 20′ include lithography, nano-imprint and micro-contact printing, wherein examples of lithography methods include photolithography and interference lithography. After carrying out an epitaxy procedure, as illustrated in FIG. 3B, a photonic crystal layer (not illustrated in the figure) including a plurality of periodically arranged photonic crystal pillars 34 are grown on the area where cavity pattern members 24 are located. Next, the patterned film layer 20′ is removed as required to finish fabrication of a pillar-type photonic crystal structure, as illustrated in FIG. 3C.

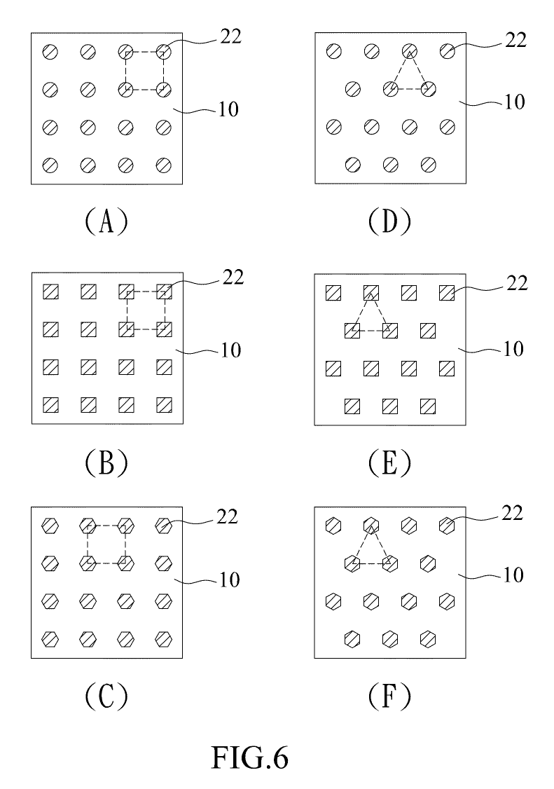

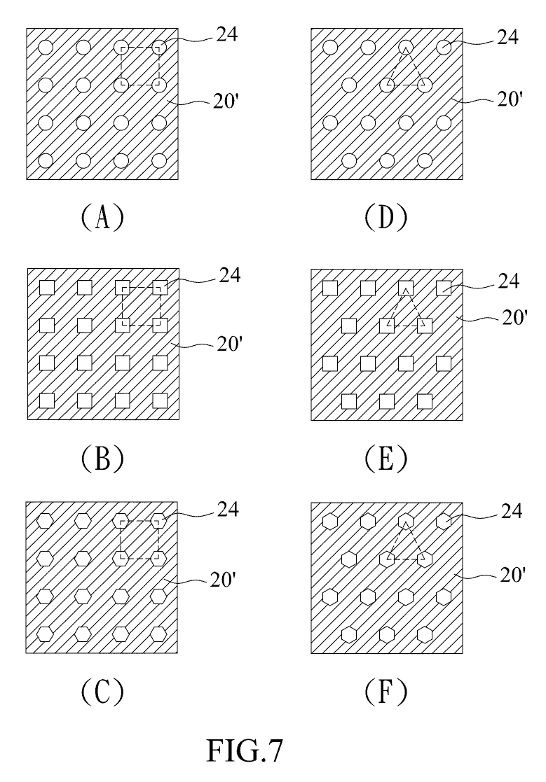

Pillar-type or cavity-type photonic crystal structures of a triangular, a circular, a square or a polygonal shape according to different embodiments can be formed by making the shape of each cavity pattern member 24 or island pattern member 22 of the patterned film layer a triangle, a circle, a square or a polygon, as illustrated by FIG. 6A to FIG. 6F, and FIG. 7A to FIG. 7F. Besides, cavity pattern members 24 or island pattern members 22 can be arranged in array wherein any three, four or any integer greater than three adjacent pattern members are arranged in a triangle, a square or a polygon, respectively. Therefore, the finished photonic crystal pillars or cavities are arranged in array wherein any three, four or any integer greater than three adjacent photonic crystal pillars or cavities are arranged in a triangle, a square or a polygon, respectively.

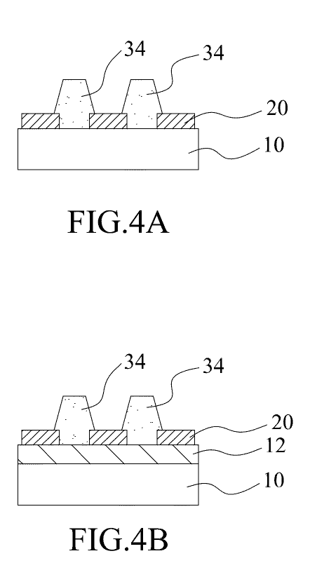

In one embodiment, a patterned film layer 20′ is formed directly on a substrate 10, and a plurality of photonic crystal pillars 34 are formed on the area outside the patterned film layer 20′, as illustrated in FIG. 4A. Referring to FIG. 4B, in another embodiment, a crystal seed layer 12 is deposited on a substrate 10. A patterned film layer 20′ including cavity pattern members is formed on the crystal seed layer 12. A plurality of the photonic crystal pillars 34 are formed on the area not covered by the patterned film layer 20′. Then, the substrate 10 can be removed while the crystal seed layer 12 remains attached to the structure constructed thereon. In this way, the crystal seed layer 12 can then re-attach to a second substrate (not illustrated in the figure), and the substrate 10 can be recycled for re-use to lower cost. A low cost material can be selected for the second substrate as required. A crystal seed layer including a GaN material can be selected for the crystal seed layer 12.

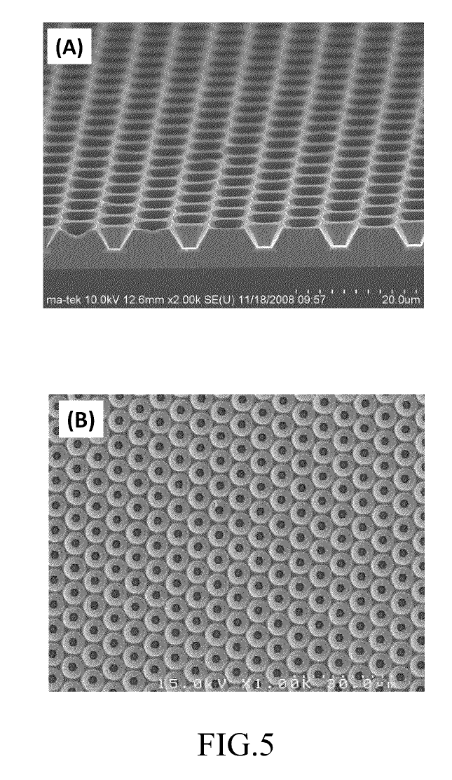

FIG. 5A and FIG. 5B are microscopic images illustrating a top view and a cross-sectional view of a photonic crystal structure fabricated according to an embodiment. As illustrated in the figure, a high quality photonic crystal structure is produced by the fabrication method according to this embodiment.

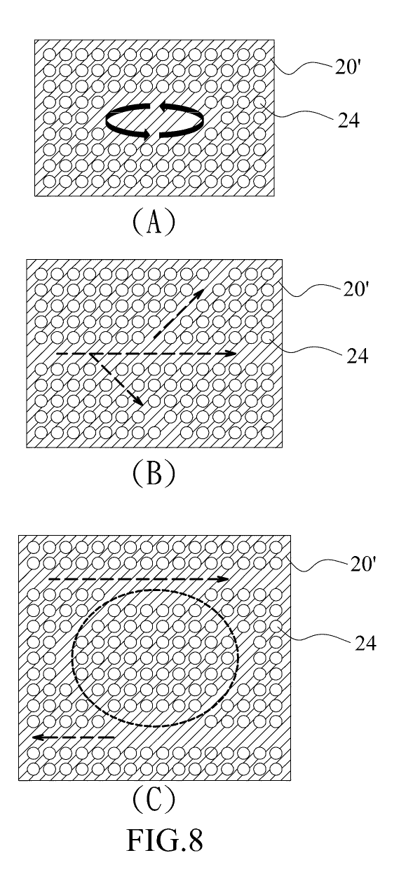

Referring to FIG. 8A, FIG. 8B and FIG. 8C, in one embodiment, island pattern members, cavity pattern members or area without pattern members can be combined according to various designs of a patterned film layer 20′, for epitaxially growing defect mode photonic crystal structures such as a resonant cavity (FIG. 8A), a light-converging or light-branching waveguide (FIG. 8B) and an annular resonant cavity (FIG. 8C).

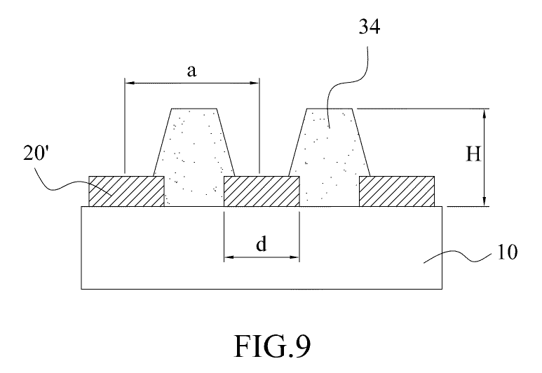

For abovementioned embodiments, since hetero-interface inhibits epitaxial growth, a patterned film layer is formed on an epitaxy substrate, and a self-constructed cavity-type or pillar-type photonic crystal structure is grown vertically by epitaxy in area outside of the patterned film layer. For epitaxial growth of crystals replicates a crystal structure regularly, a photonic crystal structure of a large area can be formed. Referring to FIG. 9, the size of photonic crystal cavities or pillars 34 can be controlled by adjusting the periodic interval a (periodic interval is the distance from the center of a pattern member to the center of adjacent pattern member) and the dimension d of the pattern member. The height H of the photonic crystal can be controlled by an epitaxy rate.

In summary, because the hetero-interface inhibits epitaxial growth, a patterned film layer is formed by film plating technology or transfer printing technology in the abovementioned embodiments. The material of the patterned film for the purpose of pattern mask is selected to be dielectric, metal or other appropriate materials. An epitaxial structure is grown vertically on the uncovered area by epitaxy technology. Since epitaxial growth does not occur where the patterned film is located, epitaxial material grows only in area outside of the patterned film. By further controlling the epitaxial growth parameter, the speed of vertical growth can be controlled to be much larger than lateral growth, thereby forming a photonic crystal structure on the uncovered area. A photonic crystal structure of a large area can be fabricated by such substrate patterning and epitaxial growth controlling method, and by calculating the direction of the epitaxial growth and the distribution of the pattern members of the patterned film, a pillar-type, cavity-type or other types of photonic crystal structures can be fabricated.

The embodiments described above are to demonstrate the technical contents and characteristics of the present invention to enable the persons skilled in the art to understand, make, and use the present invention. However, it is not intended to limit the scope of the present invention. Therefore, any equivalent modification or variation according to the spirit of the present invention is to be also included within the scope of the present invention.

What is claimed is:

1. A fabrication method of a photonic crystal structure, comprising the following steps:
providing a substrate;
forming a patterned film layer over said substrate, wherein said patterned film layer comprises a plurality of periodically arranged pattern members on said substrate; and
epitaxially growing a photonic crystal structure over said substrate such that said pattern members are exposed.

2. The fabrication method of a photonic crystal structure according to claim 1 further comprising:
forming a film layer over said substrate; and
removing a portion of said film layer and exposing said substrate for forming said patterned film layer.

3. The fabrication method of a photonic crystal structure according to claim 2, wherein said film layer is formed by sputtering, evaporation, chemical vapor deposition, chemical liquid deposition, chemical vapor epitaxy, or chemical liquid epitaxy, etc.

4. The fabrication method of a photonic crystal structure according to claim 1, wherein the material of said patterned film layer is selected from the group consisting of TiO₂, Ta₂O₅, Nb₂O₅, CeO₂, ZnO, SiO₂.

5. The fabrication method of a photonic crystal structure according to claim 1, wherein the step for forming said patterned film layer is conducted by a photolithography, a nano-imprint lithography or a micro-contact printing process.

6. The fabrication method of a photonic crystal structure according to claim 1, wherein said epitaxy procedure is conducted by a molecular beam epitaxy (MBE), a metal organic chemical vapor deposition (MOCVD) or liquid phase epitaxy (LPE) process.

7. The fabrication method of a photonic crystal structure according to claim 1, wherein said patterned film layer comprises a plurality of periodically arranged island pattern members.

8. The fabrication method of a photonic crystal structure according to claim 7, wherein said photonic crystal layer comprises a pattern formed by a plurality of photonic crystal cavities arranged periodically.

9. The fabrication method of a photonic crystal structure according to claim 8, wherein each said photonic crystal cavity is of a triangular, a circular, a square or a polygonal shape.

10. The fabrication method of a photonic crystal structure according to claim 1, wherein said patterned film layer comprises a plurality of periodically arranged cavity pattern members.

11. The fabrication method of a photonic crystal structure according to claim 10, wherein said photonic crystal layer comprises a pattern formed by a plurality of periodically arranged photonic crystal pillars.

12. The fabrication method of a photonic crystal structure according to claim 11, wherein each said photonic crystal pillar is of a triangular, a circular, a square or a polygonal shape.

13. The fabrication method of a photonic crystal structure according to claim 1, wherein said pattern members are arranged in an array and any three, four or an integer greater than three adjacent said pattern members are arranged in a triangle, a square or a polygon, respectively.

14. The fabrication method of a photonic crystal structure according to claim 1, wherein said photonic crystal layer comprises a plurality of photonic crystals arranged in an array, and any three, four or an integer greater than three adjacent said photonic crystals are arranged in a triangle, a square or a polygon, respectively.

15. The fabrication method of a photonic crystal structure according to claim 1 further comprising a step of removing said patterned film layer.

16. The fabrication method of a photonic crystal structure according to claim 15, wherein the step for removing said patterned film layer is implemented by an etching process.

17. The fabrication method of a photonic crystal structure according to claim 1, wherein a material of said substrate is selected from the group consisting of sapphire, SiC, Si, GaAs, LiAlO₂, LiGaO₂, and AlN.

18. The fabrication method of a photonic crystal structure according to claim 1 further comprising a step of forming a seed layer on said substrate.

19. The fabrication method of a photonic crystal structure according to claim 1, wherein a material of said photonic crystal layer is selected from group III-V semiconductor materials.
